(19) United States
(12) Patent Application Publication
(10) Pub. No.: US 2024/0126184 A1
(43) Pub. Date: Apr. 18, 2024

(54) BEARING SYSTEM, LITHOGRAPHY SYSTEM, AND METHOD FOR PRODUCING A BEARING SYSTEM

(71) Applicant: Carl Zeiss SMT GmbH, Oberkochen (DE)

(72) Inventors: Radhakrishna RAO, Stuttgart (DE); Robin GLORIAN, Bopfingen (DE)

(21) Appl. No.: 18/391,797

(22) Filed: Dec. 21, 2023

Related U.S. Application Data
(63) Continuation of application No. PCT/EP2022/064618, filed on May 30, 2022.

(30) Foreign Application Priority Data
Jun. 24, 2021 (DE) 10 2021 206 515.5

(51) Int. Cl. G03F 7/00

(52) U.S. Cl. CPC G03F 7/70825

(57) ABSTRACT

A bearing system (200) for supporting a first component (202) on a second component (204) of a lithography system (100A, 100B) has an adhesive (212, 212′) which secures the first and second component (202, 204) against each other. The first component (202) has at least two surfaces (216) inclined towards each other and a first adhesive surface (218) which connects the two surfaces (216), and the second component (204) has at least one ball section (220) which is received between the at least two mutually inclined surfaces (216). The ball section includes a ball surface section (226) and a second adhesive surface (230), which is arranged between two sub-sections (232, 234) of the ball surface section (226) when viewed in cross-section, and the adhesive (212, 212′) is arranged between the first and the second adhesive surface (218, 230).

### CROSS REFERENCE TO RELATED APPLICATIONS

This is a Continuation of International Application PCT/EP2022/064618, which has an international filing date of May 30, 2022, and which claims the priority of German Patent Application 10 2021 206 515.5, filed Jun. 24, 2021. The disclosures of both applications are incorporated in their respective entireties into the present Continuation by reference.

### FIELD OF THE INVENTION

The present invention relates to a mounting system, to a lithography apparatus having such a mounting system, and to a method for producing such a mounting system.

### BACKGROUND

Microlithography is used for producing microstructured components, for example, integrated circuits. The microlithography process is carried out using a lithography apparatus, which has an illumination system and a projection system. The image of a mask (reticle) illuminated by the illumination system is projected with the projection system onto a substrate, for example a silicon wafer, which is coated with a light-sensitive layer (photoresist) and arranged in the image plane of the projection system, in order to transfer the mask structure to the light-sensitive coating of the substrate.

In the case of a mechanical component which is fastened to a carrier of an optical element of the lithography apparatus with an adhesive connection, curing of the adhesive used may lead to a displacement or tilting of the component. In the case of application of the adhesive over a large area, the curing may also lead to force being admitted into the carrier of the optical element, which may lead to a significant tilting of the optical element. This can affect optical properties of the optical element, such as a lens element or a mirror.

### SUMMARY

Against this background, it is an object of the present invention is to provide an improved mounting system, a lithography apparatus having such a mounting system, and a method for producing such a mounting system.

Accordingly, a mounting system for mounting a first component on a second component of a lithography apparatus is proposed. The mounting system comprises:
the first and second component and an adhesive, which fastens the first and second components to each other, wherein
the first component has at least two mutually inclined surfaces and a first adhesive surface connecting the two surfaces,
the second component has at least one spherical section which is received between the at least two mutually inclined surfaces and comprises a spherical surface section and a second adhesive surface, the second adhesive surface being arranged, as seen in cross section, between two subsections of the spherical surface section, and
the adhesive is arranged between the first and the second adhesive surfaces.

The mounting of the first and second component on each other via the at least one spherical section which is inserted between the two mutually inclined surfaces has the effect that the first and the second component lie directly against each other only at point-contacts or small surface contacts in the region of the mounting. This makes it possible to avoid hard contact in the form of surface contact between the first component and the second component outside of this mounting. If the adhesive applied to the adhesive surfaces of the first and second component shrinks during curing, this avoidance of hard contact brings about a reduction in a force exerted on the first and/or second component. In particular, a tilting of the first and/or second component caused by adhesive shrinkage can be avoided. Even if, for example, the second component (which, for example, is lighter than the first component) is displaced or tilted by the shrinking of the adhesive during curing, the proposed mounting (and lack of surface hard contact outside the mounting) avoids the transmission of the force exerted on the first component. In particular, an effect of the adhesive curing on the position of the first and/or second component can be reduced.

For example, the lithography apparatus is a DUV or an EUV lithography apparatus. EUV stands for “extreme ultraviolet” (EUV) and refers to a wavelength of the working light between 0.1 nm and 30 nm, in particular 13.5 nm. Furthermore, DUV stands for “deep ultraviolet” (DUV) and refers to a wavelength of the working light between 30 nm and 250 nm.

The DUV or EUV lithography apparatus comprises a beam shaping and illumination system and a projection system. In particular, using the DUV or EUV lithography apparatus, the image of a mask (reticle) illuminated by the illumination system is projected with the projection system onto a substrate, for example a silicon wafer, which is coated with a light-sensitive layer (photoresist) and arranged in the image plane of the projection system, in order to transfer the mask structure to the light-sensitive coating of the substrate.

The first and/or the second component are/is in particular (a) mechanical component(s). For example, the first and/or second component is a carrier, a mount, a holder, and/or a cover. The first or second component is, for example, a carrier and/or a mount of an optical element, such as a lens element or a mirror of the DUV or EUV lithography apparatus. For example, the first or second component is a protective cover of the optical element. The first and/or second component may also be, for example, a holder for a measurement system, a diaphragm or another element of the lithography apparatus. For example, the first and/or the second component are/is made of metal.

The adhesive is in particular an adhesive which is applied in the liquid or viscous state to the first and/or the second adhesive surface and is cured to provide the adhesive connection. For example, the adhesive is a physically setting adhesive or a chemically curing adhesive. Curing of the adhesive causes it to solidify and, in the solidified state, to form a solid adhesive layer between the first and second component, in particular between the first and second adhesive surface. The adhesive layer formed in this way lies in particular directly on the first and second adhesive layers and fastens them together.

The two mutually inclined surfaces and the first adhesive surface limit or form in particular a groove in which the spherical section is received. For example, the first adhesive surface may be arranged at least partially perpendicular to a direction pointing from the first component to the second component. The first adhesive surface can, for example, connect the two mutually inclined surfaces in a straight line, as seen in cross section. In other words, the first adhesive surface can lie in a single plane. However, the first adhesive surface may also have other shapes and arrangements, as long as it connects the two mutually inclined surfaces such that, as seen in cross section, a groove closed on the side of the first adhesive surface is produced.

For example, the spherical section is formed monolithically with the second component. Alternatively, the spherical section may also be a separate element which is attached (e.g. screwed, clamped, glued) to the second component. The spherical surface section of the spherical section is curved in particular in accordance with a sphere. For example, the spherical section is flattened at an end adjacent to the first component in order to provide the second adhesive surface. The spherical surface section is interrupted in particular adjacent to the first component by the second adhesive surface.

If a spherical section is inserted between two mutually inclined surfaces, there is a small surface contact between the two mutually inclined surfaces and the spherical section, i.e. its spherical surface section, in particular a point contact or contact related to tolerance and deformation.

The two mutually inclined surfaces are rectilinear, in particular as viewed in cross section (e.g. in the case of a V groove, a conical groove, a groove in the shape of a conical segment and/or a funnel-shaped groove). Alternatively, the two mutually inclined surfaces may also be curved, as seen in cross section (e.g. in the case of a bulbous groove and/or a groove in the form of a bulbous cup).

For example, the two mutually inclined surfaces are two mutually inclined planes (e.g. in the case of a V groove). The two mutually inclined surfaces can alternatively be, for example, any surfaces which are curved per se (e.g. in the case of a conical groove, a groove in the shape of a conical segment and/or a funnel-shaped groove).

According to one embodiment, the first component comprises at least one groove, a V groove, a conical groove, a groove in the shape of a conical segment, a funnel-shaped groove, a bulbous groove, a groove in the form of a bulbous cup, and/or a funnel-shaped groove which has, in particular as seen in cross section, the two mutually inclined surfaces.

For example, this involves a V groove, and the two mutually inclined surfaces are inclined in a V-shaped manner, as seen in cross section. For example, the V groove at its tip is designed differently from a V shape (e.g. flattened or has a further depression/recess) in order to form the second adhesive surface. A V groove flattened at its tip may also be referred to as a conical segment.

According to a further embodiment, the first and the second component lie directly on each other only at point or surface contacts, which are formed by in each case two mutually inclined surfaces and a spherical section. In addition, the first and the second component are adhesively bonded to each other on the first and the second adhesive surfaces via the adhesive.

In particular, the first and the second component are adhesively bonded together exclusively outside the point or surface contacts (i.e. the point or surface contacts between the two mutually inclined surfaces and the spherical section). In particular, the adhesive connection is only an indirect contact through the adhesive.

For example, the first and the second component are only directly adjacent to each other at a total of six point or surface contacts.

According to a further embodiment, the first and second adhesive surface in each case comprises a plurality of discrete adhesive surfaces.

This makes it possible to reduce the amount of adhesive or the area covered with adhesive. As a result, the effect of the adhesive curing on the position of the first and/or second component can be reduced even further.

In particular, the mounting system, in the cured state of the adhesive, comprises a plurality of mutually spaced and discrete adhesive layers between the first and the second component. In particular, the first and second adhesive surface is not a circumferential and/or annular adhesive surface.

For example, the mounting system, in the cured state of the adhesive, comprises a total of three discrete adhesive layers spaced apart from one another.

According to a further embodiment, the first component comprises at least one recess which communicates with the at least one V groove, has the first adhesive surface and in which the adhesive is arranged. Furthermore, the second component on the at least one spherical section comprises at least one protrusion which, as viewed in cross section, protrudes between the two subsections of the spherical surface section and has the second adhesive surface. In addition, the protrusion is inserted into the recess of the first component and adhesively bonded there with the adhesive.

In particular, the first adhesive surface is formed by inner walls of the recess. In particular, the second adhesive surface is formed by outer walls of the protrusion.

By provision of the first adhesive surface in the form of inner walls of a recess, the adhesive can be applied even more specifically and in a more defined manner. In particular, an application of adhesive outside the predefined first adhesive surface can be avoided. It is also possible to better prevent the adhesive in its liquid or viscous form from spreading to regions of the first and/or second component that lie outside the first and second adhesive surface.

For example, the recess is a pot or has a pot shape. In particular, the recess is not an annular (circumferential) recess.

The protrusion, for example, has a pin shape. In particular, the protrusion is not an annular (circumferential) protrusion. For example, the protrusion is formed monolithically with the second component. Alternatively, the protrusion may also be a separate element which is attached (e.g. screwed, clamped, glued) to the second component. The protrusion protrudes in particular in the direction of the first component.

According to a further embodiment, the second component has at least one threaded pin, which at its first end section is screwed into a threaded bore of the at least one spherical section and at its second end section forms the protrusion with the second adhesive surface.

This makes it easy to manufacture the second component and in particular the protrusion.

For example, the threaded pin is a grub screw that does not have a screw head.

According to a further embodiment, the at least one protrusion is designed such that it is bendable relative to the at least one spherical section about a first bending axis and about a second bending axis perpendicular to the first bending axis. Both the first bending axis and the second bending axis are arranged perpendicular to a direction that points from the first component to the second component.

Since the protrusion can bend relative to the spherical section, it is possible to compensate for the force exerted by the adhesive during curing of the adhesive, e.g. due to adhesive shrinkage occurring.

For example, the protrusion, as described above, is formed by a threaded pin and the threaded pin, in particular its second end section, is designed such that it is bendable about the first and second bending axis.

According to a further embodiment, the at least one protrusion has at least one first leaf spring for bending about the first bending axis and at least one second leaf spring for bending about the second bending axis.

This makes it easy to realize the bending property about the first and second axis.

In particular, a main direction of extent of the first leaf spring is arranged perpendicular to a main direction of extent of the second leaf spring. In particular, the main directions of extent of the first and second leaf springs are arranged parallel to the direction from the first component to the second component.

For example, the protrusion has a pin with an inner cavity and a side wall surrounding the cavity, and the leaf springs are formed by suitable incisions (i.e. gaps) in the side wall.

According to a further embodiment, the second component comprises at least one recess which is formed in the at least one spherical section and has the second adhesive surface.

In particular, the second adhesive surface is formed by inner walls of the recess formed in the at least one spherical section.

By provision of the second adhesive surface in the form of inner walls of a recess, the adhesive can penetrate the recess. Spreading of adhesive outside the predefined first and second adhesive surfaces can thus be better avoided. For example, it is possible to better prevent the adhesive in its liquid or viscous form from spreading to regions of the first and/or second component that lie outside the first and second adhesive surface.

The recess formed in the at least one spherical section is, for example, a pot or has a pot shape. The recess formed in the at least one spherical section is in particular not an annular (circumferential) recess.

According to a further embodiment, the second component has at least one screw, which at its first end section is screwed into a threaded bore of the second component and at its second end section has a spherical head, which forms one of the at least one spherical section.

Thus, the production of the second component and in particular of the at least one spherical section can be simplified.

According to a further embodiment, one of the first and second components is a carrier of an optical element of the lithography apparatus, and the other of the first and second components is an annular cover of the optical element of the lithography apparatus.

Consequently, with the mounting system, tilting of the carrier of the optical element and thus tilting of the optical element can be better avoided. This can prevent optical properties of the optical element from being affected by the curing of the adhesive of the adhesive connection.

The annular cover is used, for example, to protect against contamination.

According to another embodiment:
the first component comprises three V grooves, which are arranged offset from one another by angles different from zero,
the second component comprises three spherical sections which are arranged offset from one another by the angles different from zero,
the first component comprises three recesses which communicate with the at least one V groove and are arranged offset from one another by the angles different from zero,
the second component comprises three protrusions, which are arranged offset from one another by the angles different from zero, and/or
the second component comprises three recesses which are formed in the at least one spherical section and are arranged offset from one another by the angles different from zero.

The angles, which are different from zero, between the above-mentioned elements are for example angles of in each case 120°. In other words, the above-mentioned elements are uniformly distributed along a circle. However, the angles, which are different from zero, between the above-mentioned elements may also have values other than 120°.

According to a further embodiment, the at least one spherical section is a spherical segment and/or a spherical wedge, or
the mounting system comprises precisely one spherical section and precisely one V groove, and the spherical section is a toroidal section, and the V groove is an annular V groove.

A spherical segment is in particular part of a solid sphere, which part is formed from the latter by an incision with a (single) plane. For example, a spherical segment has the shape of a dome with a circular disk as the base. A spherical surface of the dome forms, for example, the “spherical surface section” of the spherical section. An opening angle of the spherical segment is, for example, less than or equal to 90°. The spherical segment may also be, for example, a hemisphere (opening angle of 90°, radius of the base of the spherical segment corresponds to radius of the solid sphere).

A spherical sector is, in particular, a conical cutout of a solid sphere. In particular, a spherical sector has an opening angle of less than or equal to 90°. For example, a spherical sector is a conical cutout from a center point of the solid sphere as far as the surface thereof. For example, the spherical sector may also be a hemisphere (opening angle of 90°).

A toroidal section is in particular a section of a torus, in particular a rotational torus. In particular, a toroidal section may have the same cross-sectional area as a spherical segment.

According to a further aspect, a mounting system for mounting an annular cover on a carrier of an optical element of a lithography apparatus is proposed. The mounting system has the carrier and the annular cover. Furthermore, the carrier and the annular cover lie directly on each other at only six point or surface contacts. In addition, the carrier and the annular cover are adhesively bonded together.

In particular, the adhesive connection between the carrier and the annular cover is only an indirect contact via the adhesive. In particular, the carrier and the annular cover are adhesively bonded to each other exclusively outside the six point or surface contacts.

The above-mentioned embodiments and features of the mounting system according to the first aspect apply correspondingly to the mounting system according to the second aspect, and vice versa.

According to a further aspect, a lithography apparatus having a mounting system as described above is proposed.

According to another aspect, a method for producing a mounting system for a lithography apparatus is proposed. The method comprises the steps of:
a) providing a first component comprising at least two mutually inclined surfaces and a first adhesive surface connecting the two surfaces,
b) providing a second component comprising at least one spherical section having a spherical surface section and a second adhesive surface, the second adhesive surface being arranged, as seen in cross section, between two subsections of the spherical surface section,
c) arranging the second component on the first component such that the at least one spherical section is received between the at least two mutually inclined surfaces and the first adhesive surface is arranged adjacent to the second adhesive surface,
d) applying adhesive to the first and/or the second adhesive surface, and
e) curing the adhesive.

In particular, step d) can be carried out before or after step c).

In embodiments, the first component comprises at least one recess which is in communication with the at least two mutually inclined surfaces and has the first adhesive surface, and the adhesive is arranged in the recess in step d). In addition, the second component on the at least one spherical section comprises at least one protrusion, which has the second adhesive surface. The at least one protrusion is designed such that it is bendable relative to the at least one spherical section about a first bending axis and about a second bending axis perpendicular to the first bending axis, wherein both the first bending axis and the second bending axis are arranged perpendicular to a direction that points from the first component to the second component. Furthermore, in step c), the protrusion is inserted into the recess. In addition, a force exerted by the adhesive on the first and/or second component during the curing process in step e) is compensated for by bending the protrusion about the first and/or second bending axis.

“A” or “an” in the present case should not necessarily be understood to be restricted to precisely one element. Rather, a plurality of elements, such as two, three or more, may also be provided. Nor should any other numeral used here be understood to the effect that there is a restriction to exactly the stated number of elements. Instead, unless indicated otherwise, numerical deviations upward and downward are possible.

The embodiments and features described for the mounting system apply correspondingly to the lithography apparatus and the proposed production method, and vice versa.

Further possible implementations of the invention also include combinations which were not mentioned explicitly of features or embodiments described above or hereinafter with respect to the exemplary embodiments. In this case, a person skilled in the art will also add individual aspects as improvements or supplementations to the respective basic form of the invention.

Further advantageous refinements and aspects of the invention are the subject matter of the dependent claims and also of the exemplary embodiments of the invention that are described below. In addition, the invention will be explained in detail hereinafter on the basis of preferred embodiments with reference to the appended figures.

### BRIEF DESCRIPTION OF THE DRAWINGS

FIG. 1A shows a schematic view of an embodiment of an EUV lithography apparatus;

FIG. 1B shows a schematic view of an embodiment of a DUV lithography apparatus;

FIG. 2 shows a top view of a mounting system according to a first embodiment of the EUV or DUV lithography apparatus from FIG. 1A or 1B;

FIG. 3 shows a carrier with an annular V groove of the mounting system from FIG. 2;

FIG. 4 shows a view similar to FIG. 3, wherein the carrier has three individual V grooves instead of an annular V groove;

FIG. 5 shows a V groove spherical mounting of the mounting system from FIG. 2 before assembly;

FIG. 6 shows the V groove spherical mounting from FIG. 5 after assembly;

FIG. 7 shows a perspective view of a V groove spherical mounting of a mounting system according to a second embodiment;

FIG. 8 shows a cross-sectional view of the V groove spherical mounting from FIG. 7 before assembly;

FIG. 9 shows the V groove spherical mounting from FIG. 8 after assembly;

FIG. 10 shows a V groove spherical mounting of a mounting system according to a variant of the second embodiment after assembly;

FIG. 11 shows a shaft of a threaded pin of the V groove spherical mounting from FIG. 10;

FIG. 12 shows a V groove spherical mounting of a mounting system according to a third embodiment prior to assembly;

FIG. 13 shows the V groove spherical mounting from FIG. 12 after assembly; and

FIG. 14 shows a flow diagram, which illustrates a method for producing a mounting system according to an embodiment.

### DETAILED DESCRIPTION

Identical elements or elements having an identical function have been provided with the same reference signs in the figures, unless indicated to the contrary. It should also be noted that the illustrations in the figures are not necessarily true to scale.

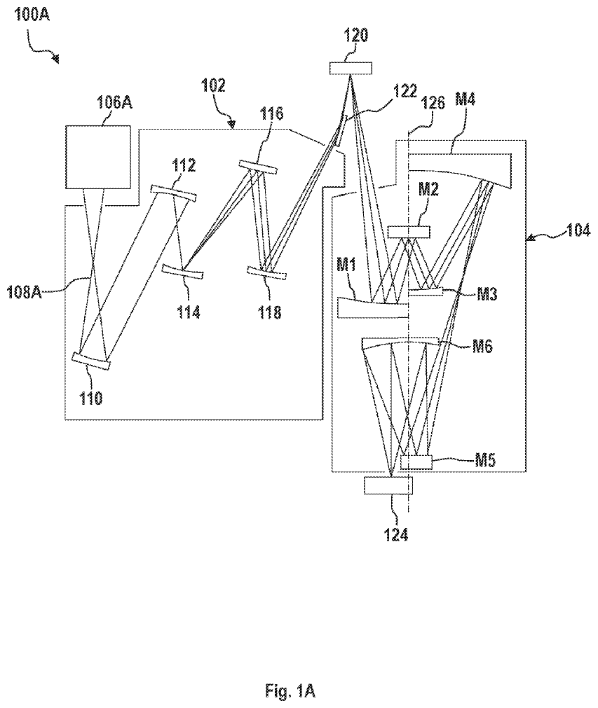

FIG. 1A shows a schematic view of an EUV lithography apparatus 100A comprising a beam shaping and illumination system 102 and a projection system 104. EUV stands for “extreme ultraviolet” (EUV) and refers to a wavelength of the working light between 0.1 nm and 30 nm, in particular 13.5 nm. The beam shaping and illumination system 102 and the projection system 104 are respectively provided in a vacuum housing (not shown), each vacuum housing being evacuated with the aid of an evacuation apparatus (not shown). The vacuum housings are surrounded by a machine room (not shown), in which drive apparatuses for mechanically moving or setting optical elements are provided. Furthermore, electrical controllers and the like may also be provided in this machine room.

The EUV lithography apparatus 100A comprises an EUV light source 106A. A plasma source (or a synchrotron), which emits radiation 108A in the EUV range (extreme ultraviolet range), which is to say for example in the wavelength range of 5 nm to 20 nm, may be provided for example as the EUV light source 106A. In the beam shaping and illumination system 102, the EUV radiation 108A is focused and the desired operating wavelength is filtered out from the EUV radiation 108A. The EUV radiation 108A generated by the EUV light source 106A has a relatively low transmissivity through air, for which reason the beam guiding spaces in the beam shaping and illumination system 102 and in the projection system 104 are evacuated.

The beam shaping and illumination system 102 illustrated in FIG. 1A comprises five mirrors 110, 112, 114, 116, 118. After passing through the beam shaping and illumination system 102, the EUV radiation 108A is guided onto a photomask (reticle) 120. The photomask 120 is likewise formed as a reflective optical element and may be arranged outside the systems 102, 104. Furthermore, the EUV radiation 108A may be directed at the photomask 120 by a mirror 122. The photomask 120 comprises a structure which is imaged onto a wafer 124 or the like in reduced form with the projection system 104.

The projection system 104 (also referred to as a projection lens) has six mirrors M1 to M6 for imaging the photomask 120 onto the wafer 124. In this case, individual mirrors M1 to M6 of the projection system 104 may be arranged symmetrically in relation to an optical axis 126 of the projection system 104. It should be noted that the number of mirrors M1 to M6 of the EUV lithography apparatus 100A is not restricted to the number shown. A greater or lesser number of mirrors M1 to M6 may also be provided. Furthermore, the mirrors M1 to M6 are generally curved on their front side for beam shaping.

FIG. 1B shows a schematic view of a DUV lithography apparatus 100B, which comprises a beam shaping and illumination system 102 and a projection system 104. In this case, DUV stands for “deep ultraviolet” and refers to a wavelength of the working light of between 30 nm and 250 nm. As has already been described with reference to FIG. 1A, the beam shaping and illumination system 102 and the projection system 104 can be arranged in a vacuum housing and/or be surrounded by a machine room with corresponding drive apparatuses.

The DUV lithography apparatus 100B comprises a DUV light source 106B. An ArF excimer laser, which emits radiation 108B in the DUV range at for example 193 nm, may be provided for example as the DUV light source 106B.

The beam shaping and illumination system 102 shown in FIG. 1B guides the DUV radiation 108B onto a photomask 120. The photomask 120 is formed as a transmissive optical element and may be arranged outside the systems 102, 104. The photomask 120 comprises a structure which is imaged onto a wafer 124 or the like in reduced form with the projection system 104.

The projection system 104 has a plurality of lens elements 128, 130 and/or mirrors 132 for imaging the photomask 120 onto the wafer 124. In this case, individual lens elements 128, 130 and/or mirrors 132 of the projection system 104 can be arranged symmetrically relative to an optical axis 126 of the projection system 104. It should be noted that the number of lens elements 128, 130 and mirrors 132 of the DUV lithography apparatus 100B is not restricted to the number shown. A greater or lesser number of lens elements 128, 130 and/or mirrors 132 can also be provided. Furthermore, the mirrors 132 are generally curved on their front side for beam shaping.

An air gap between the last lens element 130 and the wafer 124 may be replaced by a liquid medium 134 having a refractive index >1. The liquid medium 134 may be for example high-purity water. Such a set-up is also referred to as immersion lithography and has an increased photolithographic resolution. The medium 134 may also be referred to as an immersion liquid.

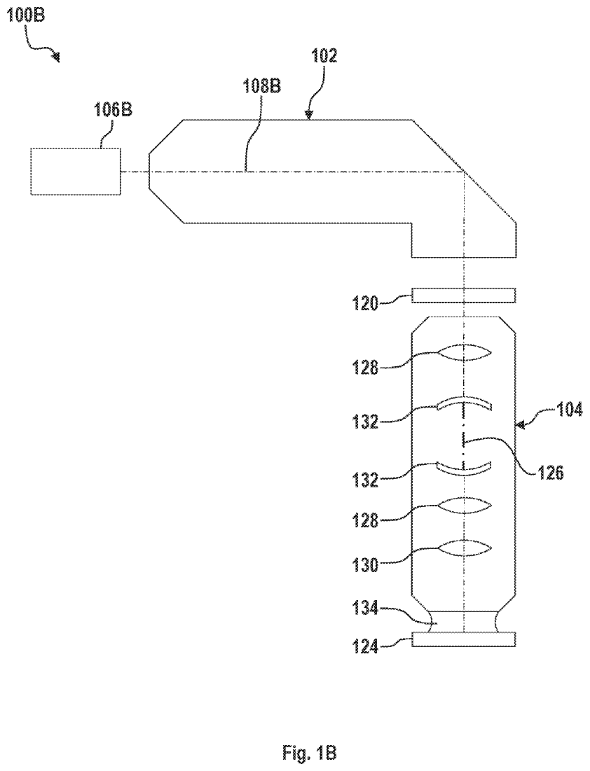

FIG. 2 shows a top view of a mounting system 200 of the EUV or DUV lithography apparatus 100A, 100B. The mounting system 200 has a first mechanical component 202 and a second mechanical component 204 and is used for mounting these two components 202, 204 on each other.

In the example shown in FIG. 2, the mounting system 200 is used for mounting an annular cover 204 on a carrier 202 of an optical element 206. In FIG. 2, the annular cover 204 partially covers both the carrier 202 and the optical element 206 from above, in particular in a respective edge region. The annular cover 204 is used, for example, to protect against contamination. The annular cover 204 is, for example, designed and arranged such that it allows an air flow between the optical element 206 and the cover 204. In FIG. 2, the annular cover 204 is shown only by dashed lines for better visibility of the optical element 206 and the carrier 202. The annular cover 204 and the carrier 202 are, for example, made of metal.

The optical element 206 is, for example, the final lens element 130, arranged in front of the wafer 124, of the DUV lithography apparatus 100B from FIG. 1B. In other examples, the optical element 206 may also be another optical element of the EUV or DUV lithography apparatus 100A, 100B from FIGS. 1A, 1B. For example, the optical element 206 may also be one of the mirrors 110-118, 122, M1-M6 of the EUV lithography apparatus 100A (FIG. 1A) or one of the lens elements 128 or the mirrors 132 of the DUV lithography apparatus 100B (FIG. 1B).

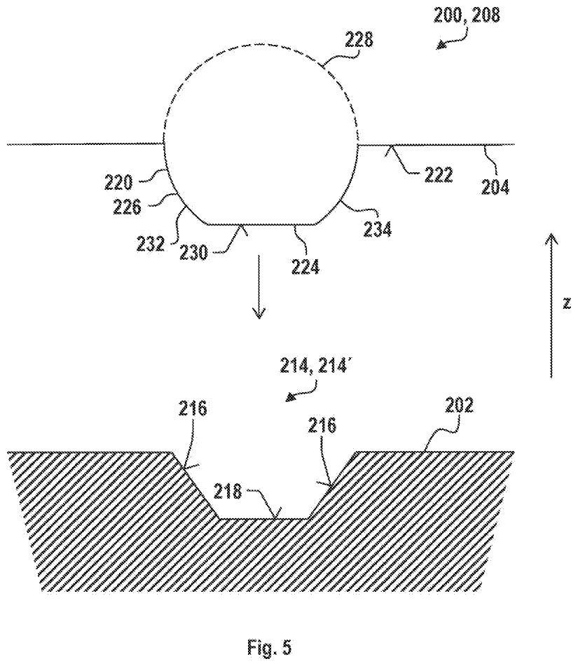

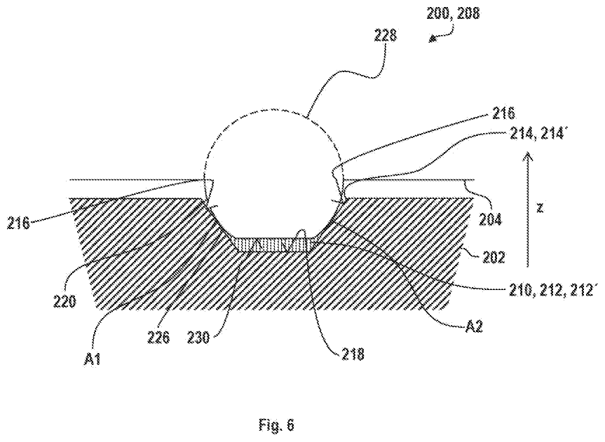

The annular cover 204 is, as described in detail below, mounted on the carrier 202 via a point mounting, for example a V groove spherical mounting 208 (FIG. 5), via which between the first and second component 202, 204 there are only point contacts or small surface contacts related to tolerance and deformation in the region of the mounting. Thus, an unambiguous mounting of the annular cover 204 on the carrier 202 is possible, in which a hard surface contact between the annular cover 204 and the carrier 202, both of which are, for example, made of metal, outside the mounting is avoided. In addition, the annular cover 204 is firmly adhesively bonded to the carrier 202 via an adhesive connection 210 (FIG. 6), which is arranged outside the point or surface contacts of the V groove spherical mounting 208.

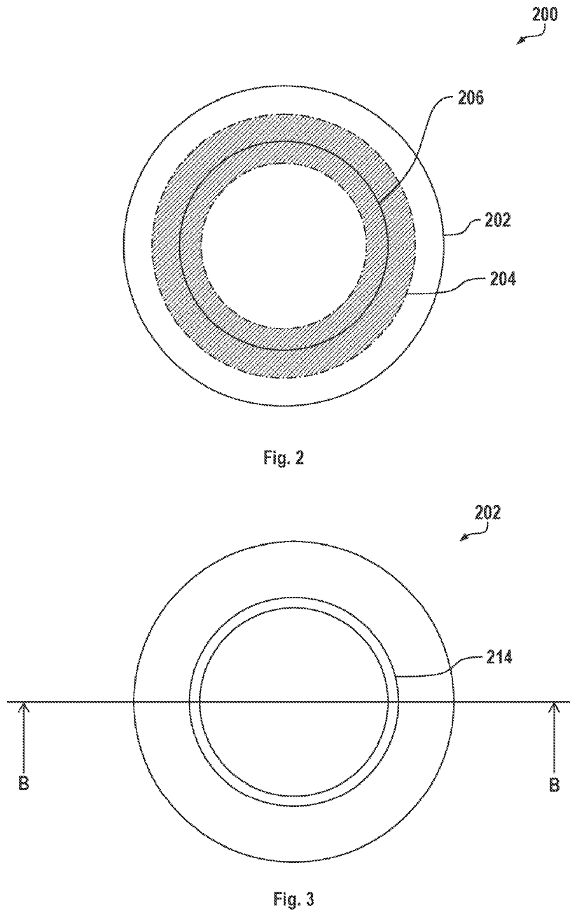

FIG. 3 shows the carrier 202 in the same orientation as in FIG. 2, but without the optical element 206 and without the annular cover 204. As can be seen in FIG. 3, the carrier 202 has a groove, in the example shown an annular V groove 214. FIG. 5 shows the V groove 214 in a radial cross section (section along line BB in FIG. 3).

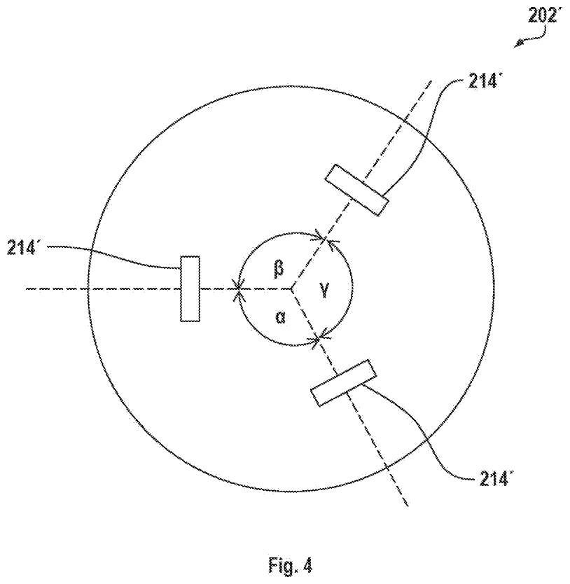

Instead of an annular V groove 214 (FIG. 3), the carrier 202′ can also have three individual V grooves 214′, as shown in FIG. 4. In this case, the three individual V grooves 214′ are arranged offset with respect to one another at angles of α, β, γ. In the example shown in FIG. 4, the three individual V grooves 214′ are arranged offset with respect to one another at equal angles of in each case 120° (i.e. α=β=γ=120°). In other examples, the three individual V grooves may also be arranged offset with respect to one another at different angles α, β, γ from zero. The cross section of the V groove 214, 214′ shown in FIGS. 5 and 6 corresponds both to the cross section of the annular V groove 214 (FIG. 3) and to the cross section of one of the three V grooves 214′ (FIG. 4). It is noted that instead of the annular V groove 214 (FIG. 3) or the three individual V grooves 214′, one or more differently shaped grooves, such as a conical groove, a groove in the shape of a conical segment, a funnel-shaped groove, a bulbous groove and/or a groove in the form of a bulbous cup may be used.

As shown in FIG. 5, the V groove 214, 214′ has two mutually inclined surfaces 216. Furthermore, the V groove 214, 214′ has a first adhesive surface 218 connecting the two surfaces 216 for the adhesive connection to the annular cover 204. In particular, the V groove 214, 214′ has a V shape cut off at the bottom (in FIG. 5), in which a cut wall has the first adhesive surface 218. In the example shown in FIG. 5, the first adhesive surface 218 is arranged perpendicular to a direction Z, which points from the carrier 202 to the cover 204.

To mount the cover 204 on the carrier 202 via the V groove spherical mounting 208, the cover 204 has three spherical sections 220, one of which is shown in cross section in FIGS. 5 and 6. FIG. 5 shows the V groove spherical mounting 208 in a state before the spherical section 220 was introduced into the V groove 214 or 214′. FIG. 6 shows the V groove spherical mounting 208 in a state in which the spherical section 220 is located in the V groove 214 or 214′.

Each of the three spherical sections 220 protrudes from a lower surface 222 (FIG. 5) of the cover 204 in the direction of the carrier 202. The spherical section 220 shown in FIG. 5 is in particular a hemisphere which is flattened at a lower end 224 in FIG. 5. Each of the three spherical sections 220 comprises a spherical surface section 226 which is spherically curved in accordance with a solid sphere 228. In addition, each of the three spherical sections 220 has a second adhesive surface 230. The second adhesive surface 230 is arranged in FIG. 5 at the flattened end 224 of the spherical section 220. In addition, in the example shown in FIG. 5, the second adhesive surface 230 is arranged perpendicular to the direction Z. The second adhesive surface 230, as seen in the cross section of FIG. 5, is arranged in particular between two subsections 232 and 234 of the spherical surface section 226.

As shown in FIG. 6, liquid adhesive 212 is inserted between the first and second adhesive surfaces 218, 230. In addition, each of the three spherical sections 220 is inserted into the one annular V groove 214 (FIGS. 3 and 6) or into one of the three individual V grooves 214′ (FIGS. 4 and 6) and mounted therein such that a spherical section 220 rests at two support points or two small support surfaces A1, A2 on the mutually inclined surfaces 216 of the V groove 214, 214′. In particular, between the three spherical sections 220 and the V groove 214 (or the three V grooves 214′) there are only point contacts or small surface contacts related to tolerance and deformation. For example, between the three spherical sections 220 and the V groove 214 (or the three V grooves 214′) there are a total of six point contacts or surface contacts A1, A2. In other words, the cover 204 is in contact with the carrier 202 via the V groove spherical mounting 208 only at point or surface contacts in the region of the mounting 208.

In other examples, instead of three spherical sections 220, a single toroidal section (not shown), which also has a radial cross section as shown in FIG. 5, can also be used.

The adhesive 212 applied in liquid form between the first and second adhesive surfaces 218, 230 is cured and in solidified form forms an adhesive layer 212′ (FIG. 6). The adhesive connection 210 between the annular cover 204 and the carrier 202 is produced by the fixed adhesive layer 212′.

During curing, the adhesive 212, 212′ can shrink and thereby exert a force on the annular cover 204 and/or the carrier 202. Since the adhesive 212, 212′ is applied only at three discrete locations between the cover 204 and the carrier 202, namely on the second adhesive surface 230 of the three spherical sections 220 arranged on the flattened side 224 (FIG. 5), a force exerted by the adhesive 212, 212′ is reduced compared to a situation in which an adhesive is applied in a planar and annular manner between a component, such as an annular cover 204, and another component, such as a carrier 202.

If, during the curing of the adhesive 212, 212′, a displacement and/or tilting of the cover 204 occurs, the V groove spherical mounting 208 (FIG. 6) between the cover 204 and the carrier 202 thus prevents the carrier 202 from thereby also being tilted. Consequently, it is possible in particular to prevent an optical element 206 held by the carrier 202 (FIG. 2), such as a lens element or a mirror, from being displaced and/or tilted.

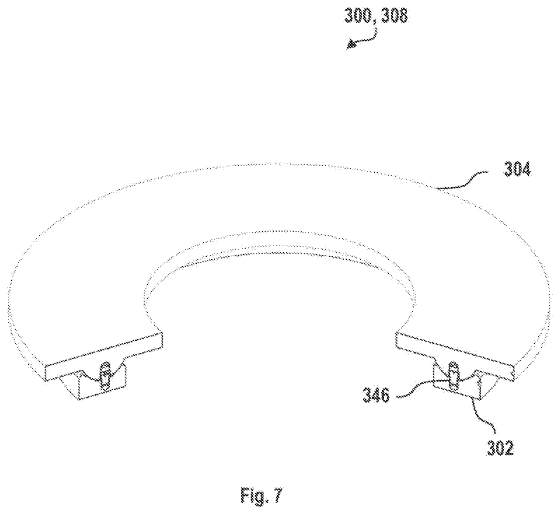

FIGS. 7-9 show a second embodiment of the mounting system 300 with a V groove spherical mounting 308 and an adhesive connection 310. The mounting system 300 according to the second embodiment has a carrier 302 for an optical element 206 (similarly to the carrier 202 according to the first embodiment) and an annular cover 304 (similarly to the annular cover 204 according to the first embodiment).

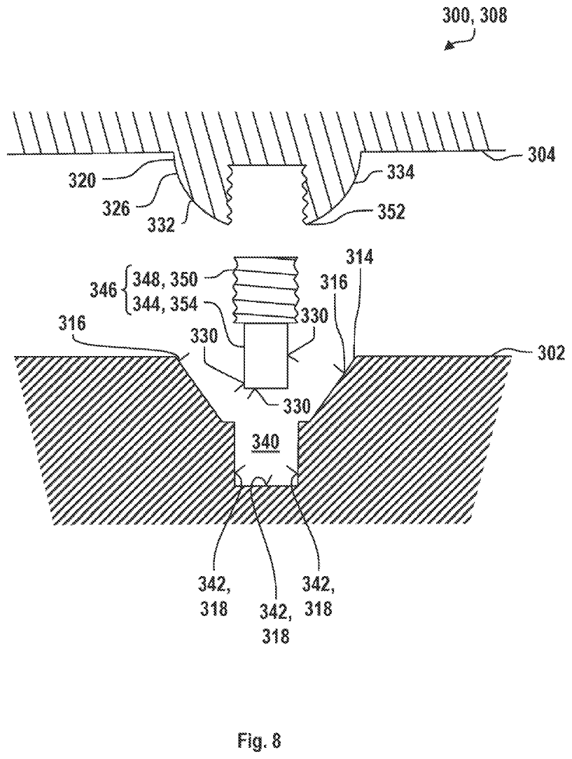

The carrier 302 has a V groove 314 (similarly to the V groove 214, 214′, FIG. 5) and three recesses 340 (FIG. 8) communicating with the V groove 314. As in the case of the first embodiment, the V groove 314 may be an annular V groove corresponding to the V groove 214 (FIG. 3) or three individual V grooves corresponding to the V groove 214′ (FIG. 4) may be present. The recesses 340 (FIG. 8) communicating with the V groove 314 are in particular cup-shaped and formed at three discrete, spaced apart locations on the carrier 302. In particular, the recesses 340 are not circumferential or annular.

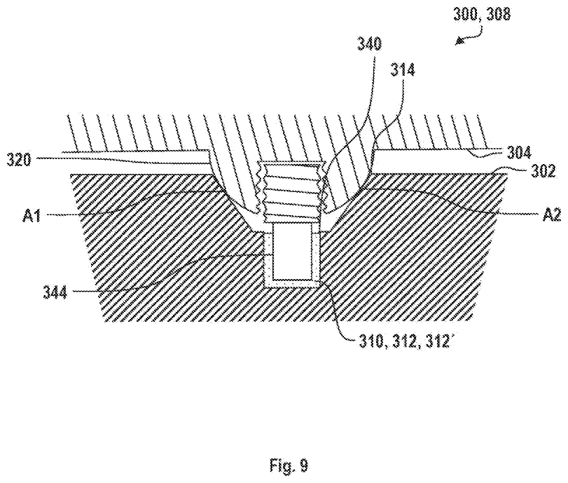

Each of the recesses 340, of which one is shown in cross section in FIGS. 8 and 9, has an adhesive surface 318 (first adhesive surface) on its inner walls 342, in which the adhesive 312 (FIG. 9) is disposed.

Furthermore, the annular cover 304 has three spherical sections 320, one of which is shown in cross section in FIGS. 8 and 9. The spherical sections 320, like the spherical sections 220 of the first embodiment (FIG. 5), have a spherical surface section 326 with two subsections 332, 334.

The spherical sections 320 differ from the spherical sections 220 of the first embodiment (FIG. 5) by a protrusion 344 arranged on the spherical section in question. The protrusion 344 may be formed monolithically with the spherical section 320 (not shown). Alternatively, the protrusion, as illustrated in FIGS. 7-9, can be provided by a separate element 346, which is fastened to the spherical section 320. In the example shown, the protrusion 344 is provided by a threaded screw 346, which has a thread 350 on a first end section 348.

The threaded screw 346 is screwed into a threaded bore 352 of the spherical section 320 (FIG. 9) such that the protrusion 344 provided by a shaft 354 (second end section 354) of the threaded screw 346, as seen in cross section, protrudes between the two subsections 332, 334 of the spherical surface section 326. The protrusion 344 also has a second adhesive surface 330 for adhesive fastening to the first adhesive surface 318 of the recess 340.

For the mounting and fastening of the annular cover 304 on the carrier 302, an adhesive 312 (FIG. 9) is filled in liquid form into the recess 340 of the carrier 302. Then the annular cover 304 is arranged on the carrier 320 such that the protrusion 344 is inserted into the recess 340 of the carrier 302 and is adhesively bonded there by the adhesive 312, 312′. In addition, as in the first embodiment, the spherical section 320 is inserted into the V groove 314 (FIG. 9) such that the spherical section 320 lies on mutually inclined surfaces 316 of the V groove 314 in a discrete point or surface contact A1, A2. Curing of the adhesive 312 forms a solid adhesive layer 312′, which produces the adhesive connection 310 between the annular cover 304 and the carrier 302.

Using the recess 340 with the first adhesive surface 318 and the protrusion 344 with the second adhesive surface 330, the adhesive 312 can be applied in a targeted manner. In particular, it can be avoided that the adhesive 312 in its liquid form spreads to regions of the annular cover 304 and/or the carrier 302 outside the first and second adhesive surfaces 318, 330.

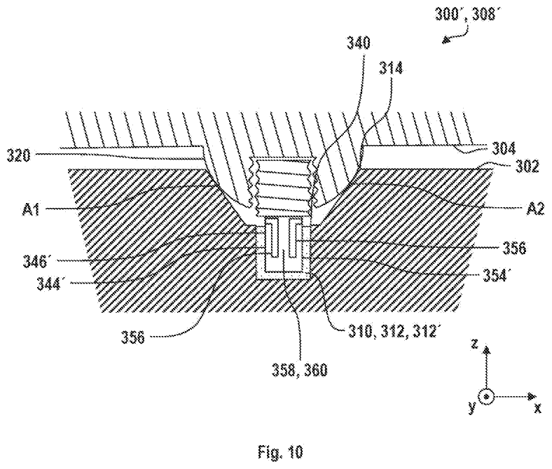

FIG. 10 shows a variant of the second embodiment of the mounting system 300′ with the V groove spherical mounting 308′. In the following, only differences over the second embodiment are described. In the mounting system 300′, the protrusion 344′ is designed such that it can bend relative to the spherical section 320 in order to compensate for forces during the curing of the adhesive 312, 312′. In particular, the protrusion 344′ can bend relative to the spherical section 320 about a first bending axis X (parallel to the X direction in FIG. 10) and about a second bending axis Y perpendicular to the first bending axis X (parallel to the Y direction in FIG. 10). Both the first bending axis X and the second bending axis Y are arranged perpendicular to the direction Z, which points from the carrier 302 to the cover 304.

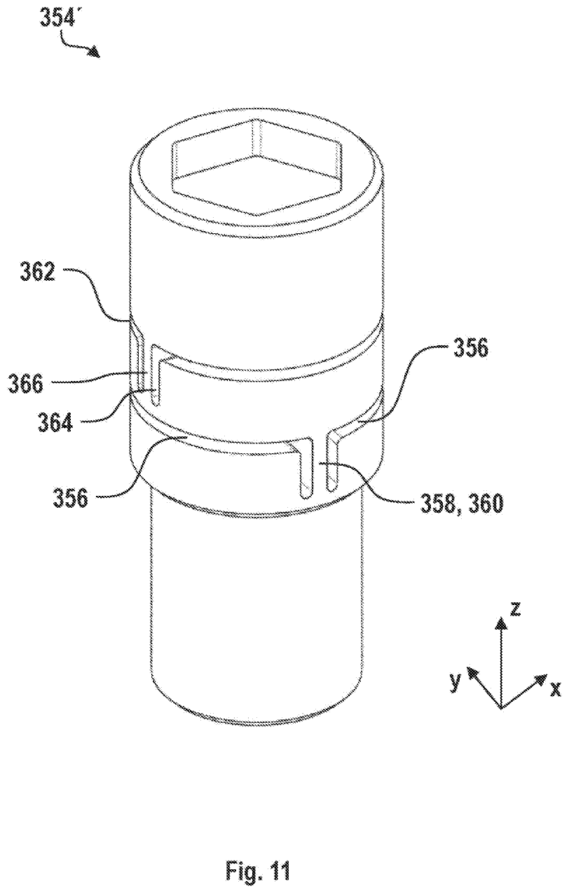

In the example shown in FIG. 10, the bendability of the protrusion 344′ is realized by incisions 356 in a wall of the shank 354′ of the threaded screw 346′. Although FIG. 10 shows a cross section, two incisions 356, which would actually only be visible in a top view, are shown in FIG. 10 for illustrative reasons. A web 358 which forms a first leaf spring 360 remains between the two incisions 356. On the rear side of the shank 354′, a leaf spring 360 which is symmetrical to the first leaf spring 360 is formed by the two incisions 356. The first two leaf springs 360 each have a main plane of extent in the Y-Z plane and allow the shank 354′ (i.e. the protrusion 344′) to bend about a bending axis in the X direction. Furthermore, the shank 354′ has two further incisions 362, 364 (FIG. 11), through which two second leaf springs 366 are formed (one of which is visible in FIG. 11). The two second leaf springs 366 have a main plane of extent in the X-Z plane and allow the shank 354′ (i.e. the protrusion 344′) to bend about a bending axis in the Y direction.

Owing to the bendability of the shank 346′, compensation for a force occurring during the curing of the adhesive 312, 312′ is possible. This compensation makes it possible to prevent tilting of the carrier 302 and thus of the optical element 206 (FIG. 2) from occurring due to the curing of the adhesive 312, 312′ of the adhesive connection 310.

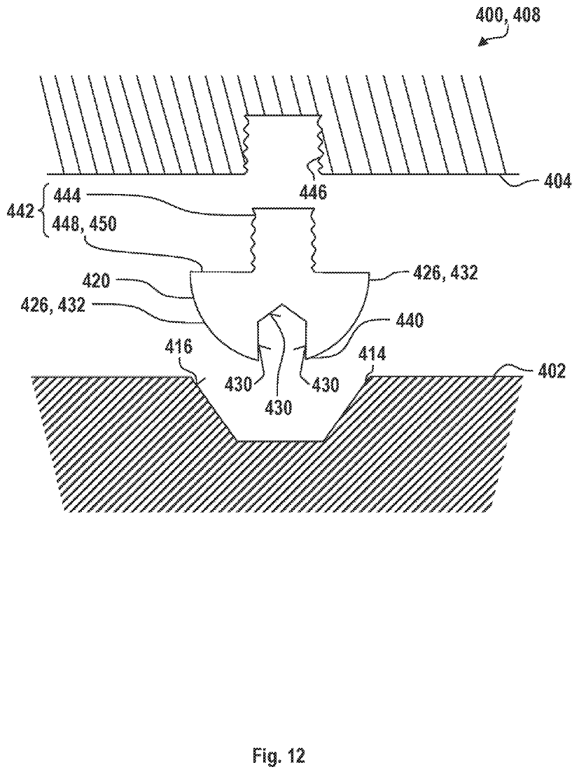

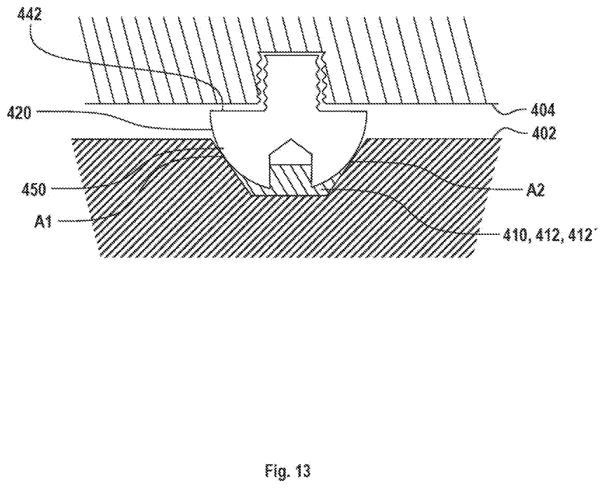

FIGS. 12 and 13 show a third embodiment of the mounting system 400 with a V groove spherical mounting 408 and an adhesive connection 410. The mounting system 400 according to the third embodiment has a carrier 402 for an optical element 206 (similarly to the carrier 202 according to the first embodiment) and an annular cover 404 (similarly to the annular cover 204 according to the first embodiment). In the following, only differences over the first embodiment are described.

In the mounting system 400, the spherical section 420 has a recess 440, which has the second adhesive surface 430. In addition, the spherical section 420 is not formed monolithically with the annular cover 404 (as in the first embodiment, FIG. 5), but rather as a separate element 442. In particular, the mounting system 400 has a screw 442 as a separate element, which at its first end section 444 has a thread, with which it can be screwed into a threaded bore 446 of the annular cover 404. In addition, the screw 442 at its second end section 448 has a spherical head 450, which forms the spherical section 420 with the recess 440. In other examples, the spherical section 420 formed by a spherical head 450 of a separate screw 442, as shown in FIGS. 12 and 13, can also be realized without the recess 440. FIG. 13 shows the mounting system 400 of the third embodiment in the assembled state with the mounting at a support point or a discrete contact surface A1, A2 and the cured adhesive connection 410.

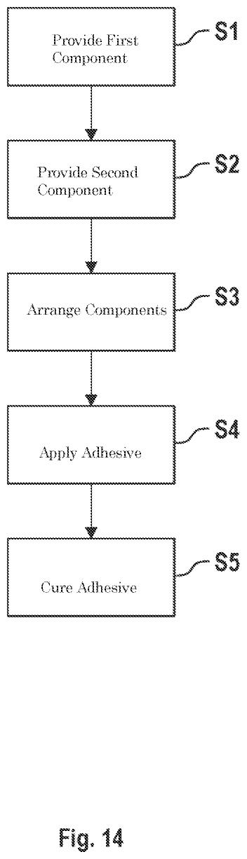

In the following, with reference to FIGS. 5, 6 and 14, a method for producing a mounting system 200 for a lithography apparatus 100A, 100B according to a first embodiment is described.

In a first step S1 of the method, a first component 202, such as a carrier 202 of an optical element 206 (FIGS. 2 and 5), is provided, which comprises at least two mutually inclined surfaces 216 and a first adhesive surface 218 connecting the two surfaces 216.

In a second step S2 of the method, a second component 204, such as an annular cover 204 (FIGS. 2 and 5), is provided, which comprises at least one spherical section 220 with a spherical surface section 226 and a second adhesive surface 230. The second adhesive surface 230, as seen in cross section, is arranged between two subsections 232 of the spherical surface section 226.

In a third step S3 of the method, the second component 204 is arranged on the first component 202 such that the at least one spherical section 220 is received between the at least two mutually inclined surfaces 216 and the first adhesive surface 218 is arranged adjacent to the second adhesive surface 230.

In a fourth step S4 of the method, an adhesive 212 is applied to the first and/or second adhesive surface 218, 230.

In a fifth step S5 of the method, the adhesive 212 is cured such that it forms a solid adhesive layer 212′.

The present invention has been described on the basis of exemplary embodiments From the disclosure given, those skilled in the art will not only understand the present invention and its attendant advantages, but will also find apparent various changes and modifications to the structures and methods disclosed. The applicant seeks, therefore, to cover all such changes and modifications as fall within the spirit and scope of the invention, as defined by the appended claims, and equivalents thereof.

### LIST OF REFERENCE SIGNS

100A EUV lithography apparatus
100B DUV lithography apparatus
102 Beam-shaping and illumination system
104 Projection system
106A EUV light source
106B DUV light source
108A EUV radiation
108B DUV radiation
110 Mirror
112 Mirror
114 Mirror
116 Mirror
118 Mirror
120 Photomask
122 Mirror
124 Wafer
126 Optical axis
128 Lens element
130 Mirror
132 Medium
200 Mounting system
202 First component
204 Second component
206 Optical element
208 Mounting
210 Adhesive connection
212, 212′ Adhesive
214 Groove
216 Surface
218 First adhesive surface
220 Spherical section
222 Surface
224 End
226 Spherical surface section
228 Solid sphere
230 Second adhesive surface
232 Subsection
234 Subsection
300, 300′ Mounting system
302 Component (carrier)
304 Component (cover)
308, 308′ Mounting
310 Adhesive connection
312, 312′ Adhesive
314 Groove
316 Surface
318 First adhesive surface
320 Spherical section
326 Spherical surface section
330 Second adhesive surface
332 Subsection
334 Subsection
340 Recess
342 Inner wall
344, 344′ Protrusion
346 Element (threaded screw)
348 End section
350 Thread
352 Threaded bore
354 Shank (end section)
356 Incision
358 Web
360 Leaf spring
362 Incision
364 Incision
366 Leaf spring
400 Mounting system
402 Component (carrier)
404 Component (cover)
408 Mounting
410 Adhesive connection
420 Spherical section
430 Second adhesive surface
440 Recess
442 Screw
444 End section
446 Threaded bore
448 End section
450 Spherical head
A1 Support point/support surface
A2 Support point/support surface
M1 Mirror
M2 Mirror
M3 Mirror
M4 Mirror
M5 Mirror
M6 Mirror
S1-S5 Method step
X Direction, axis
Y Direction, axis
Z Direction

What is claimed is:

1. A mounting system for mounting components of a lithography apparatus, comprising:
a first component, a second component and an adhesive which fastens the first and the second components to each other, wherein:
the first component comprises at least two mutually inclined surfaces and a first adhesive surface connecting the two mutually inclined surfaces,
the second component comprises at least one spherical section which is configured to be received between the at least two mutually inclined surfaces and to comprise a spherical surface section and a second adhesive surface, the second adhesive surface being arranged, as seen in cross section, between two subsections of the spherical surface section, and
the adhesive is arranged between the first and the second adhesive surfaces.

2. The mounting system as claimed in claim 1, wherein the first component comprises at least one groove which is configured as a V groove, a conical groove, a groove having a conical segment shape, a funnel-shaped groove, a bulbous groove, a groove having a bulbous cup shape, and/or a funnel-shaped groove, and which comprises, as seen in cross section, the two mutually inclined surfaces.

3. The mounting system as claimed in claim 1, wherein the first and the second components lie directly against each other only at point-contacts or surface-contacts which are formed respectively by the two mutually inclined surfaces and the spherical section, and, in addition are adhesively bonded to each other on the first and the second adhesive surfaces with the adhesive.

4. The mounting system as claimed in claim 1, wherein the first and the second adhesive surfaces each comprise a plurality of discrete adhesive surfaces.

5. The mounting system as claimed in claim 1, wherein
the first component comprises at least one V groove and at least one recess which communicates with the at least one V groove, which comprises the first adhesive surface and in which the adhesive is arranged,
the second component comprises, on the at least one spherical section, at least one protrusion which, as seen in cross section, protrudes between the two subsections of the spherical surface section and comprises the second adhesive surface, and
the protrusion is configured to insert into the recess of the first component and to be adhesively bonded there with the adhesive (312, 312′).

6. The mounting system as claimed in claim 5, wherein the second component comprises at least one threaded pin, which at a first end section thereof is configured to screw into a threaded bore of the at least one spherical section and at a second end section thereof forms the protrusion with the second adhesive surface.

7. The mounting system as claimed in claim 5, wherein the at least one protrusion is configured to bend relative to the at least one spherical section about a first bending axis and about a second bending axis perpendicular to the first bending axis, wherein both the first bending axis and the second bending axis are arranged perpendicular to a direction that points from the first component to the second component.

8. The mounting system as claimed in claim 7, wherein the at least one protrusion has at least one first leaf spring configured to bend about the first bending axis and at least one second leaf spring configured to bend about the second bending axis.

9. The mounting system as claimed in claim 1, wherein the second component comprises at least one recess which is formed in the at least one spherical section and which has the second adhesive surface.

10. The mounting system as claimed in claim 1, wherein the second component comprises at least one screw, which at a first end section thereof is configured to screw into a threaded bore of the second component and at a second end section thereof has a spherical head that forms the at least one spherical section.

11. The mounting system as claimed in claim 1, wherein one of the first and the second components is a carrier of an optical element of the lithography apparatus, and the other of the first and the second components is an annular cover of the optical element of the lithography apparatus.

12. The mounting system as claimed in claim 1, wherein
the first component comprises three V grooves, which are arranged angularly offset from one another by angles (α, γ, β) different from zero,
the second component comprises three spherical sections which are arranged offset from one another by the angles (α, β, γ) different from zero,
the first component comprises three recesses which communicate respectively with the three V grooves and are arranged offset from one another by the angles (α, β, γ) different from zero, and
the second component comprises:
a) three protrusions which are arranged offset from one another by the angles (α, β, γ) different from zero, and/or
b) three recesses which are formed in the at least one spherical section and are arranged offset from one another by the angles (α, β, γ) different from zero.

13. The mounting system as claimed in claim 1, wherein
the at least one spherical section is a spherical segment and/or a spherical wedge, or
the mounting system comprises precisely one spherical section and precisely one V groove, and the spherical section is a toroidal section, and the V groove is an annular V groove.

14. A lithography apparatus, comprising an illumination system and a projection system, wherein the lithography apparatus comprises a mounting system as claimed in claim 1.

15. A method for producing a mounting system for a lithography apparatus, comprising:
a) providing a first component comprising at least two mutually inclined surfaces and a first adhesive surface connecting the two surfaces,
b) providing a second component comprising at least one spherical section having a spherical surface section and a second adhesive surface, wherein the spherical surface section comprises two subsections and the second adhesive surface is arranged, as seen in cross section, between the two sub sections of the spherical surface section,
c) arranging the second component on the first component such that the at least one spherical section is received between the at least two mutually inclined surfaces and the first adhesive surface is arranged adjacent to the second adhesive surface,
d) applying adhesive to the first and/or to the second adhesive surface, and
e) curing the adhesive.
